(19) United States
(12) Patent Application Publication
(10) Pub. No.: US 2009/0092931 A1
(43) Pub. Date: Apr. 9, 2009

(54) Methods of forming a blocking pattern using a photosensitive composition and methods of manufacturing a semiconductor device

(76) Inventors: Kyong-Rim Kang, Seongnam-si (KR); Young-Ho Kim, Yongin-si (KR); Jae-Hyun Kim, Yongin-si (KR); Sun-Yul Ahn, Anyang-si (KR); Nam-Uk Choi, Suwon-si (KR)

Correspondence Address: LEE & MORSE, P.C., 3141 FAIRVIEW PARK DRIVE, SUITE 500, FALLS CHURCH, VA, 22042, US

(21) Appl. No.: 12/222,573

(22) Filed: Aug. 12, 2008

(30) Foreign Application Priority Data
Aug. 14, 2007 (KR) 10-2007-0081623

(51) Int. Cl. G03F 7/20

(52) U.S. Cl. 430/323; 430/325

(57) ABSTRACT

A method of forming a blocking pattern includes forming a preliminary blocking layer on first and second regions of a substrate, the preliminary blocking layer being formed of a photosensitive composition including a siloxane polymer, a cross-linking agent, a photoacid generator, and a thermal acid generator, selectively exposing to light a first portion of the preliminary blocking layer, the first portion of the preliminary blocking layer being formed on the first region of the substrate, such that a cross-linked pattern is formed on the first region of the substrate, and removing a second portion of the preliminary blocking layer, the second portion of the preliminary blocking layer being formed on the second region of the substrate.

### BACKGROUND

1. Field

Example embodiments relate to methods of forming a blocking pattern and to methods of manufacturing a semiconductor device including the same. More particularly, example embodiments relate to methods of forming a blocking pattern using a photosensitive composition and to methods of manufacturing a semiconductor device including the same.

2. Description of the Related Art

Generally, a capacitor may include a lower electrode, a dielectric layer, and an upper electrode, and may be employed in a memory device, e.g., a DRAM device. As a degree of integration of the memory device increases, an area of a unit cell including at least one capacitor in the memory device may decrease. In order to improve capacitance of the capacitor in a highly integrated memory device, e.g., a memory device having a gigabyte of data storage capacity, the capacitor may have a volumetric structure, e.g., a box type structure or a cylindrical type structure, having a high aspect ratio. For example, a cylindrical capacitor may include a lower electrode having a cylindrical shape.

The conventional lower electrode of the capacitor may include forming a mold layer pattern, forming a blocking pattern on the mold layer pattern, e.g., by a chemical vapor deposition (CVD) process or by using a photoresist, and forming the lower electrode. Once the lower electrode is formed, the blocking pattern and the mold layer pattern may be removed.

The conventional blocking pattern formed by a film deposition process, e.g., CVD, however, may include voids therein. Further, the blocking pattern formed by the film deposition process may not be sensitive to light, so an additional photolithography process may be required to form the blocking pattern in a specific region of the mold layer pattern.

The conventional blocking pattern formed by using a photoresist, however, may cause plasma damage to the lower electrode, when the blocking pattern is removed from the lower electrode by an ashing process. Further, portions of the photoresist may not be easily removed from the lower electrode by the ashing process when the photoresist is baked, so polymeric contaminants, i.e., portions of the photoresist, may remain on the lower electrode to cause defects in a semiconductor device.

Further, a conventional etching process for removing the mold layer pattern may shift, pull, or remove portions of the lower electrode. In particular, a conventional process of forming lower electrodes on the conventional mold pattern may include forming a portion of a lower electrode in an edge die region of a substrate, i.e., a peripheral portion of the substrate. As a result, an abnormal lower electrode may be formed in the edge die region of the substrate, and may be removed or shifted in a subsequent etching process, i.e., during removal of the mold layer pattern. Removal or shifting of the abnormal electrode may cause a defect in the semiconductor device.

### SUMMARY

Example embodiments are therefore directed to methods of forming a blocking pattern and methods of manufacturing a semiconductor device including the same, which substantially overcome one or more of the disadvantages of the related art.

It is therefore a feature of an example embodiment to provide methods of forming a blocking pattern using a photosensitive composition that may simplify a semiconductor manufacturing process.

It is another feature of an example embodiment to provide methods of forming a blocking pattern using a photosensitive composition that may reduce generation of defects in a semiconductor device.

It is yet another feature of an example embodiment to provide methods of manufacturing a semiconductor device using a blocking pattern with one or more of the above features.

At least one of the above and other features and advantages of the present invention may be realized by providing a method of forming a blocking pattern, including forming a preliminary blocking layer on first and second regions of a substrate, the preliminary blocking layer being formed of a photosensitive composition including a siloxane polymer, a cross-linking agent, a photoacid generator, and a thermal acid generator, selectively exposing to light a first portion of the preliminary blocking layer, the first portion of the preliminary blocking layer being formed on the first region of the substrate, such that a cross-linked pattern may be formed on the first region of the substrate, and removing a second portion of the preliminary blocking layer, the second portion of the preliminary blocking layer being formed on the second region of the substrate. The first region of the substrate may include an edge die region, and the second region of the substrate may include a die forming region.

The method may further include curing the preliminary blocking layer after removing the second portion of the preliminary blocking layer from the second region, curing the preliminary blocking layer including performing a thermal treatment process. Removing the second portion of the preliminary blocking layer may include completely removing the preliminary blocking layer from the second region of the substrate, such that only the cross-linked pattern on the first region of the substrate may be cured by the thermal treatment process. Removing the second portion of the preliminary blocking layer may include partially removing the preliminary blocking layer from the second region of the substrate to form a partial layer on the second region of the substrate, such that both the cross-linked pattern on the first region and the partial layer on the second region may be cured by the thermal treatment process. Removing the second portion of the preliminary blocking layer from the second region may be performed by a developing process. The photosensitive composition may be formed of about 0.1 parts to about 20 parts by weight of the cross-linking agent, about 0.01 parts to about 20 parts by weight of the photoacid generator, and about 0.01 parts to about 20 parts by weight of the thermal acid generator, based on about 100 parts by weight of the siloxane polymer. The photosensitive composition may be formed of a siloxane polymer including silicon-oxygen bonds in a backbone and at least one labile group substituent, the labile group being an acid-labile group and/or a heat-labile group.

At least one of the above and other features and advantages of the present invention may be realized by providing a method of forming a blocking pattern, including forming a pattern structure with openings on a substrate, the substrate including a die forming region and an edge die region, forming a preliminary blocking layer on the pattern structure to fill the openings, forming the preliminary blocking layer including coating a photosensitive composition on the pattern structure, the photosensitive composition including a siloxane polymer, a cross-linking agent, a photoacid generator, and a thermal acid generator, selectively exposing to light a first portion of the preliminary blocking layer to form a first preliminary blocking pattern on the pattern structure in the edge die region of the substrate, the first preliminary blocking pattern including a cross-linked portion, removing a second portion of the preliminary blocking layer, the second portion of the preliminary blocking layer being formed in the die forming region of the substrate, such that a second preliminary blocking pattern may be formed in the openings of the pattern structure in the die forming region of the substrate, and curing the first and the second preliminary blocking patterns to form a first blocking pattern in the edge die region and a second blocking pattern in the die forming region.

Forming the pattern structure on the substrate may include forming a layer on the substrate, forming a photoresist film on the layer, forming a photoresist pattern on the layer by performing an exposure process on the photoresist film using a first reticle, the first reticle defining a first reticle image corresponding to a first number of dies, and etching the layer using the photoresist pattern as an etching mask to form the pattern structure on the substrate. Selectively exposing to light the preliminary blocking layer may include using a second reticle, the second reticle defining a second reticle image corresponding to a second number of dies, and the second number of dies being larger than zero and smaller than the first number of dies.

At least one of the above and other features and advantages of the present invention may be realized by providing a method of manufacturing a semiconductor device, including forming at least one conductive structure on a substrate, the substrate including a die forming region and an edge die region, forming a mold layer pattern on the substrate, the mold layer pattern including at least one opening exposing the conductive structure, forming a conductive layer on sidewalls and a bottom of the opening and on an upper surface of the mold layer pattern, forming a preliminary blocking layer on the conductive layer to fill the opening, forming the preliminary blocking layer including coating a photosensitive composition on the conductive layer, the photosensitive composition including a siloxane polymer, a cross-linking agent, a photoacid generator and a thermal acid generator, selectively exposing to light a first portion of the preliminary blocking layer to form a first preliminary blocking pattern on the conductive layer in the edge die region of the substrate, the first preliminary blocking pattern including a cross-linked portion, removing a second portion of the preliminary blocking layer, the second portion of the preliminary blocking layer being formed in the die forming region of the substrate, such that a second preliminary blocking pattern may be formed in the opening of the mold layer pattern in the die forming region of the substrate, curing the first and the second preliminary blocking patterns by a thermal treatment process to form a first blocking pattern in the edge die region and a second blocking pattern in the die forming region, and removing a portion of the conductive layer in the die forming region to form at least one lower electrode in the die forming region.

The method may further include removing the first blocking pattern from the edge die region, and the mold layer pattern and the second blocking pattern from the die forming region, after forming the lower electrode in the die forming region. Removing the first and second blocking patterns and the mold layer pattern may be performed using a solution including hydrogen fluoride, ammonium fluoride and water. Forming the mold layer pattern on the substrate may include forming a mold layer on the substrate, forming a photoresist film on the mold layer, forming a photoresist pattern on the mold layer by performing an exposure process on the photoresist film using a first reticle defining a first reticle image corresponding to a first number of dies, and etching the mold layer using the photoresist pattern as an etching mask to form the mold layer pattern on the substrate. Selectively exposing to light the first portion of the preliminary blocking layer may be performed using a second reticle defining a second reticle image corresponding to a second number of dies, the second number of dies being larger than zero and smaller than the first number of dies. The thermal treatment process may be performed at a temperature of about 100° C. to about 300° C.

### BRIEF DESCRIPTION OF THE DRAWINGS

The above and other features and advantages of the present invention will become more apparent to those of ordinary skill in the art by describing in detail example embodiments thereof with reference to the attached drawings, in which:

FIGS. 1-3 illustrate cross-sectional views of stages in a method of forming a blocking pattern in accordance with an example embodiment;

FIGS. 4-8 illustrate cross-sectional views of stages in a method of forming a blocking pattern in accordance with another example embodiment;

FIGS. 9-21 illustrate cross-sectional views of stages in a method of forming a semiconductor device in accordance with an example embodiment;

FIG. 22 illustrates a schematic diagram of a die forming region and an edge die region in a substrate in accordance with an example embodiment;

FIGS. 23 and 24A-24C illustrate schematic diagrams of reticle images in accordance with example embodiments;

FIG. 25 illustrates a schematic diagram of a substrate after an exposure process forming a mold layer pattern in accordance with an example embodiment;

FIG. 26 illustrates a schematic diagram of a substrate after an exposure process forming a blocking pattern in an edge die region in accordance with an example embodiment; and

FIG. 27 illustrates a schematic diagram of a substrate after an exposure process forming a mold layer pattern in accordance with a conventional method.

### DETAILED DESCRIPTION OF EXAMPLE EMBODIMENTS

Korean Patent Application No. 10-2007-0081623, filed on Aug. 14, 2007, in the Korean Intellectual Property Office, and entitled: “Methods of Forming a Blocking Pattern Using a Photosensitive Composition and Methods of Manufacturing a Semiconductor Device,” is incorporated by reference herein in its entirety.

Example embodiments will now be described more fully hereinafter with reference to the accompanying drawings, in which exemplary embodiments of the invention are illustrated. Aspects of the invention may, however, be embodied in different forms and should not be construed as limited to the embodiments set forth herein. Rather, these embodiments are provided so that this disclosure will be thorough and complete, and will fully convey the scope of the invention to those skilled in the art.

In the figures, the dimensions of layers, elements, and regions may be exaggerated for clarity of illustration. It will also be understood that when a layer or element is referred to as being “on” another layer, element, or substrate, it can be directly on the other layer, element, or substrate, or intervening layers and/or elements may also be present. Further, it will also be understood that when a layer or element is referred to as being “between” two layers or elements, it can be the only layer or element between the two layers or elements, or one or more intervening layers and/or elements may also be present. In addition, it will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like reference numerals refer to like elements throughout.

As used herein, the expressions “at least one,” “one or more,” and “and/or” are open-ended expressions that are both conjunctive and disjunctive in operation. For example, each of the expressions “at least one of A, B, and C,” “at least one of A, B, or C,” “one or more of A, B, and C,” “one or more of A, B, or C” and “A, B, and/or C” includes the following meanings: A alone; B alone; C alone; both A and B together; both A and C together; both B and C together; and all three of A, B, and C together. Further, these expressions are open-ended, unless expressly designated to the contrary by their combination with the term “consisting of.” For example, the expression “at least one of A, B, and C” may also include an nth member, where n is greater than 3, whereas the expression “at least one selected from the group consisting of A, B, and C” does not.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

The terminology used herein is for the purpose of describing particular example embodiments only and is not intended to be limiting of the present invention. As used herein, the singular forms a, an” and “the” are intended to include the plural forms as well, unless the context clearly indicates otherwise.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention. In addition, as used herein, a “die” may also be a chip and “chip” may also be a die.

Unless otherwise defined, all terms including technical and scientific terms used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Method of Forming a Blocking Pattern

FIGS. 1-3 illustrate cross-sectional views of stages in a method of forming a blocking pattern in accordance with some example embodiments. For example, the method illustrated in FIGS. 1-3 may provide a blocking pattern for blocking, e.g., substantially covering a surface, at least a portion of an edge die region of a substrate.

Referring to FIG. 1, a preliminary blocking layer 12 may be formed on a substrate 10 by coating the substrate 10 with a photosensitive composition. The substrate 10, e.g., a semiconductor substrate, may have a die forming region and an edge die region, and the preliminary blocking layer 12 may be formed on both the die forming region and edge die region of the substrate 10, as illustrated in FIG. 1. A pattern structure (not illustrated), e.g., a conductive structure, an insulation structure, a gate, a pad, a plug, a wiring, etc, may be formed on the substrate 10 in the die forming region and the edge die region.

The die forming region of the substrate 10 may be in a central portion of the substrate 10, e.g., a portion of the substrate 10 in which a complete semiconductor chip may be formed. The edge die region may be a peripheral portion of the substrate 10, and may surround the die forming region of the substrate 10. The edge die region may be smaller than the die forming region, so a complete semiconductor chip, e.g., a capacitor, may not be formed therein. In other words, a size of the edge die region of the substrate 10 may be insufficient to include a semiconductor chip therein.

The photosensitive composition for forming the preliminary blocking layer 12 may be formed as follows. The photosensitive composition may include a siloxane polymer, a cross-linking agent, a photoacid generator, and a thermal acid generator. The photosensitive composition may include about 0.1 parts to about 20 parts by weight of the cross-linking agent, about 0.01 parts to about 20 parts by weight of the photoacid generator and about 0.01 parts to about 20 parts by weight of the thermal acid generator, based on about 100 parts by weight of the siloxane polymer. The amounts of the components of the photosensitive composition may be adjusted in accordance with properties of the blocking pattern, the amount of acid generated by heat or light or a curing temperature.

The siloxane polymer of the photosensitive composition may be a polymer having silicon-oxygen bonds in a backbone and at least one labile group substituent, e.g., an acid-labile group substituent and/or a heat-labile group substituent. For example, the siloxane polymer may include a repeating unit represented by Formula 1 below,

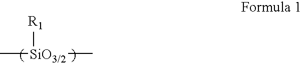

where R₁ may be a C₁-C₁₀ alkyl, a cycloalkyl, an aryl or a silylalkyl, each of which may have an acid-labile group and/or a heat-labile group. Non-limiting examples of the acid-labile and/or heat-labile group may include a —COOR₃ ester, a —OCOOR₄ carbonate, a —OR₅ ether, an acetal, a ketal, etc. Non-limiting examples of R₃ in the —COOR₃ ester may include t-butyl, adamantyl, norbornyl, isobornyl, 2-methyl-2-adamantyl, 2-methyl-2-isobornyl, 2-butyl-2-adamantyl, 2-propyl-2-isobornyl, 2-methyl-2-tetracyclododecenyl, 2-methyl-2-dihydrodicyclopentadienyl-cyclohexyl, etc. A non-limiting example of R₄ in the —OCOOR₄ carbonate may be t-butoxycarbonyl. Non-limiting examples of the —OR₅ ether may include tetrahydropyranyl ether, trialkylsilyl ether, etc.

In another example, the siloxane polymer of the photosensitive composition may be a copolymer having a first repeating unit represented by Formula 1 and a second repeating unit represented by Formula 2 below,

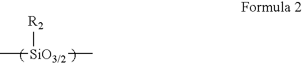

where R₂ may be hydrogen, hydroxyl, a C₁-C₁₀ alkyl, a C₁-C₁₀ alkoxy, a C₁-C₁₀ haloalkyl, etc.

In another example, the siloxane polymer of the photosensitive composition may be a polymer having a chemical structure represented by Formula 3 below,

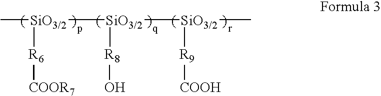

where R₆ may be a divalent moiety, e.g., —(CH₂)n-, —O—, —CO(CH₂)n-, —COO(CH₂)n-,

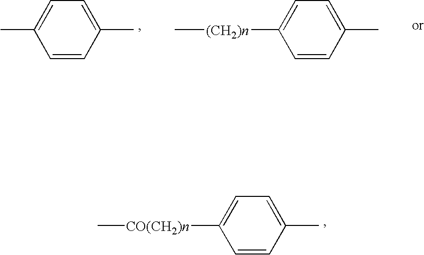

R₇ may be t-butyl, adamantyl, norbornyl, isobornyl, 2-methyl-2-adamantyl, 2-methyl-2-isobornyl, 2-butyl-2-adamantyl, 2-propyl-2-isobornyl, 2-methyl-2-tetracyclododecenyl or 2-methyl-2-dihydrodicyclopentadienyl-cyclohexyl, R₈ may be a divalent moiety, e.g., —(CH₂)n-, —CO(CH₂)n- and —COO(CH₂)n-, R₉ may be a divalent moiety, e.g., —(CH₂)m-, n may be an integer from 1 to 10, and m may be an integer from 0 to 10. In Formula 3, each of p, q and r may be a positive integer, and a ratio of p, q and r may be adjusted to improve hydrophilicity of the photosensitive composition, solubility of the photosensitive composition in a developing solution, and a cross-linking of the blocking pattern. For example, the ratio of p, q and r may be about 1:1:1 to about 10:5:3.

The siloxane polymer of the photosensitive composition may have a molecular weight adjusted to improve viscosity of the photosensitive composition, coatability of the photosensitive composition on the substrate 10, etch resistance of the blocking pattern, and solubility of the photosensitive composition in a developing solution. For example, the siloxane polymer may have a weight-average molecular weight in a range of about 5,000 to about 20,000.

The cross-linking agent of the photosensitive composition may be any suitable cross-linking compound capable of initiating a cross-linking reaction in the presence of acid or heat. Non-limiting examples of the cross-linking agent may include one or more of a melamine compound, e.g., one or more of alkoxymethyl melamine, alkylated melamine, etc., a urea compound, e.g., one or more of urea, alkoxymethylene urea, N-alkoxymethylene urea, tetrahydro-1,3,4,6-tetramethylimidazo[4,5-d]imidazole-2,5-(1H,3H)-dione, ethylene urea, etc., uril, e.g., one or more of benzoguanamine, glycol uril, etc., and so forth.

The thermal acid generator of the photosensitive composition may be any suitable thermal acid generator capable of generating acid in response to an initiation of heat. A non-limiting example of the thermal acid generator may be a sulfonate compound. Non-limiting examples of the sulfonate compound may include compounds represented by Formulae 4-11. These may be used alone or in a combination thereof.

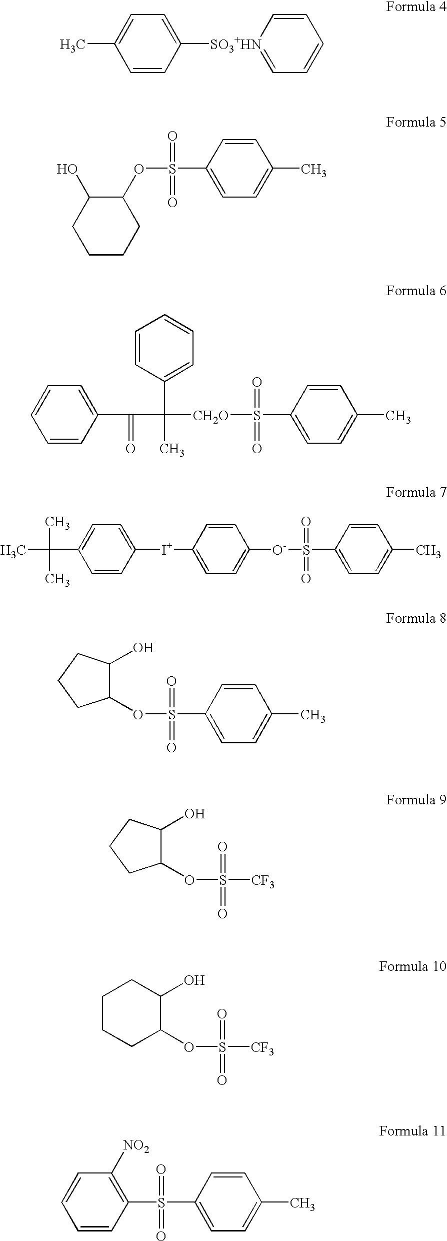

The photoacid generator of the photosensitive composition may be any suitable photoacid generator capable of generating acid when exposed to light. Non-limiting examples of the photoacid generator may include one or more of a sulfonium salt, a triarylsulfonium salt, an iodonium salt, a diaryliodonium salt, a nitrobenzyl ester, a disulfone, a diazo-disulfone, a sulfonate, trichloromethyltriazine, N-hydroxysuccinimide triflate, etc.

More specifically, non-limiting examples of the photoacid generator may include one or more of triphenylsulfonium triflate, triphenylsulfonium antimony salt, diphenyliodonium triflate, diphenyliodonium antimony salt, diphenyliodonium perfluorooctanesulfonate, methoxydiphenyliodonium triflate, pyrogallol tris(alkylsulfonate), di-t-butyldiphenyliodonium triflate, 2,6-dinitrobenzyl sulfonate, norbornene-dicarboxyimide triflate, triphenylsulfonium nonaflate, norbornene dicarboxyimide nonaflate, diphenyliodonium nonaflate, methoxydiphenyliodonium nonaflate, di-t-butyldiphenyliodonium nonaflate, N-hydroxysuccinimide nonaflate, triphenylsulfonium perfluorooctanesulfonate, methoxyphenyliodonium perfluorooctanesulfonate, di-t-butyldiphenyliodonium triflate, norbornene dicarboxyimide perfluorooctanesulfonate, N-hydroxysuccinimide perfluorooctanesulfonate, etc.

The photosensitive composition may further include an additive, e.g., a surfactant and/or an organic base, in an amount of about 0.00001 parts to about 10 parts by weight, based on about 100 parts by weight of the siloxane polymer. Non-limiting examples of the surfactant may include one or more of a polyoxyalkylene alkylether, an ammonium dodecylbenzenesulfonate, an alkylphosphate, etc. The organic base may control a diffusion distance of acid generated from the photoacid generator and/or the thermal acid generator. Non-limiting examples of the organic base may include one or more of triethylamine, triisobutylamne, triisooctylamine, triisodecylamine, diethanolamine, triethanolamine, etc.

The photosensitive composition may further include a solvent. The solvent may dissolve the above-mentioned components, and may adjust viscosity of the photosensitive composition. Non-limiting examples of the solvent may include one or more of ether, lactone, ester, ketone, alcohol, amide, sulfoxide, nitrile, aliphatic hydrocarbon and aromatic hydrocarbon.

The photosensitive composition according to example embodiments of the present invention may include a siloxane polymer, as opposed to an organic polymer with a hydrocarbon backbone, so the photosensitive composition may have increased solubility in an etching solution for removing silicon oxides, e.g., after the photosensitive composition is cured. Thus, a cured photosensitive composition according to example embodiments may be efficiently removed, i.e., substantially entirely removed from the substrate 10, using the etching solution for removing silicon oxides, so substantially no contaminants may remain on the substrate 10, as compared to a conventional composition including the organic polymer with the hydrocarbon backbone.

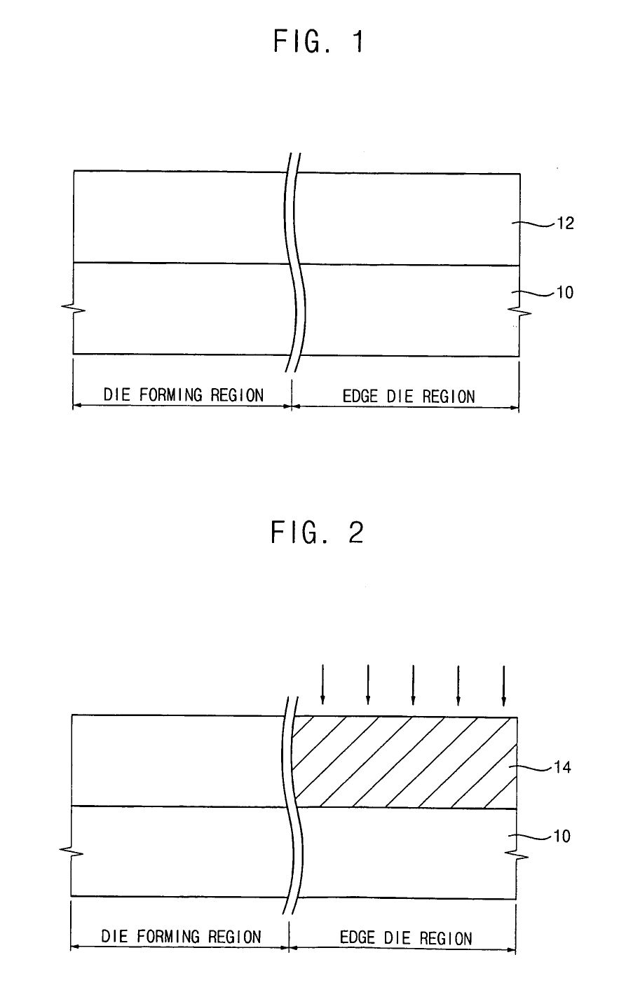

Once the preliminary blocking layer 12 including the photosensitive composition is formed on the substrate 10, a portion of the preliminary blocking layer 12 in the edge die region of the substrate 10 may be exposed to light, as illustrated in FIG. 2. Since the photosensitive composition used to form the preliminary blocking layer 12 may include a photoacid generator and a cross-linking agent, exposure of a portion of the preliminary blocking layer 12 to light may activate acid generation by the photoacid generator, thereby triggering a cross-linking reaction activated by the cross-linking agent. Thus, the portion of the preliminary blocking layer 12 that is exposed to light may be altered, i.e., cross-linked, to become insoluble in a developing solution. In other words, when an exposure process exposes a portion of the preliminary blocking layer 12 positioned on the edge die region of the substrate 10 to light, the exposed portion of the preliminary blocking layer 12 may be cross-linked and transformed into a blocking pattern 14. Accordingly, the blocking pattern 14 may be on the edge die region of the substrate 10, and may be insoluble in the developing solution. It is noted that a portion of the preliminary blocking layer 12 positioned on the die forming region of the substrate 10 may not be exposed to light, so the portion of the preliminary blocking layer 12 on the die forming region of the substrate may be soluble in the developing solution.

The exposure process for exposing the portion of the preliminary blocking layer 12 in the edge die region of the substrate 10 to light may be performed using a reticle defining at least one reticle image that corresponds to at least one die. For convenience of description, as used herein, when a reticle image is referred to as “corresponding” to a predetermined number of dies (or chips), the reticle image may define a pattern for the predetermined number of dies. For example, a reticle image corresponding to nine dies may define a pattern for nine dies. Each of a plurality of reticle images may correspond to substantially fewer dies than a maximum number of dies that may be exposed to light in one shot (i.e., at one time). It is noted that when the substrate 10 is exposed to light using the reticle, even though a number of dies exposed to light in one shot may be relatively small and require a relatively large number of shots, since the exposure process may be performed only in the edge die region of the substrate 10, i.e., a substantially smaller area than the die forming region of the substrate 10, a total time required for performing the exposure process according to example embodiments may be relatively short.

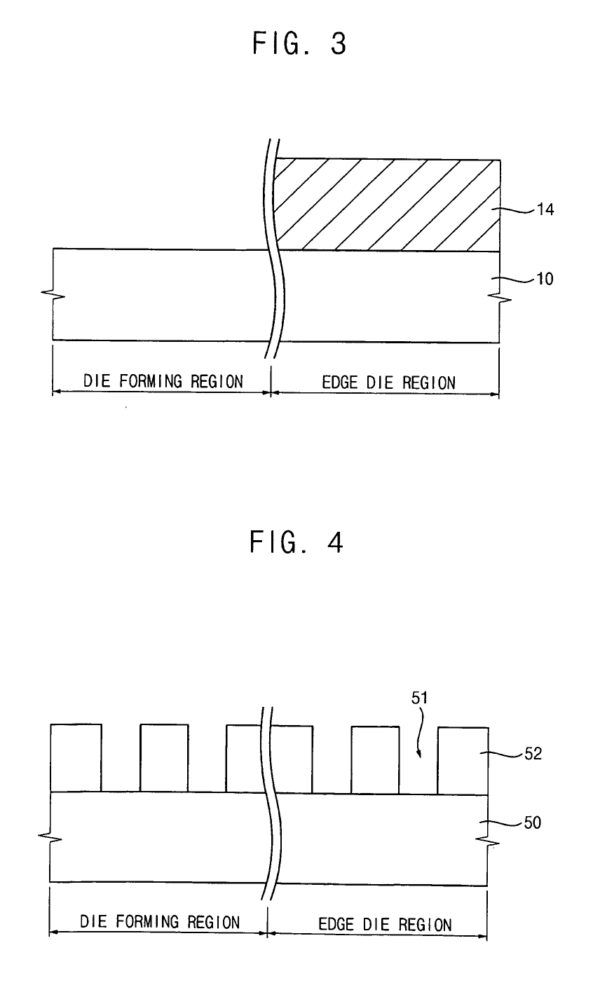

Once the blocking pattern 14 is formed on the substrate 10 in the edge die region thereof, the substrate 10 may be developed using a developing solution to remove at least a portion of the preliminary blocking layer 12 that is disposed in the die forming region, as illustrated in FIG. 3. The preliminary blocking layer 12 may be completely removed from the substrate 10 or the preliminary blocking layer 12 may be only partially removed from the substrate 10. An amount of the preliminary blocking layer 12 removed from the substrate 10 may be adjusted in accordance with a length of time that the preliminary blocking layer 12 is immersed in the developing solution. For example, as illustrated in FIG. 3, a portion of the preliminary blocking layer 12 disposed in the die forming region may be completely removed, e.g., to expose an entire upper surface of the substrate 10 in the die forming region thereof. In another example (not illustrated), when a pattern structure is formed on the substrate 10, e.g., only an upper portion of the preliminary blocking layer 12 may be removed, so a portion of the preliminary blocking layer 12 in the die forming region may remain on the substrate 10 after the developing process to protect or block a portion of the pattern structure in the die forming region.

As further illustrated in FIG. 3, since the blocking pattern 14 is insoluble in the developing solution, the blocking pattern 14 may remain in the edge die region of the substrate 10 after the developing process. The blocking pattern 14 may be cured via a thermal treatment. The blocking pattern 14 may substantially cover or block the edge die region of the substrate 10, e.g., cover an entire upper surface of the substrate 10 in the edge die region, so the blocking pattern 14 may protect a portion of the substrate 10.

FIGS. 4-8 illustrate cross-sectional views of stages in a method of forming a blocking pattern in accordance with another example embodiment. For example, the embodiment illustrated in FIGS. 4-8 may provide a method of forming patterns that may completely block, i.e., cover, an edge die region of a substrate and may partially block a die forming region of the substrate.

Referring to FIG. 4, a pattern structure 52 having at least one opening 51 may be formed on a substrate 50, e.g., a silicon wafer. The substrate 50 may have a die forming region and an edge die region, as illustrated in FIG. 4. The substrate 50 may be substantially same as the substrate 10 described previously with reference to FIGS. 1-3 and, therefore, its detailed description will not be repeated. The pattern structure 52 may be formed on the substrate 50 in the die forming region and in the edge die region.

In particular, a pattern layer (not illustrated) may be formed on the substrate 50, e.g., by a chemical vapor deposition (CVD) process, followed by formation of a photoresist film (not illustrated) on the pattern layer, e.g., by a spin-coating process. A first exposure process may be performed on the photoresist film to form a photoresist pattern (not illustrated) on the pattern layer in the die forming region and the edge die region of the substrate 50. The pattern layer may be etched using the photoresist pattern as an etching mask to form the pattern structure 52 having the openings 51 on the substrate 50. It is noted that the first exposure process may be performed using a first reticle that defines a reticle image corresponding to a maximum number of dies that may be exposed to light in one shot, i.e., first number of dies. Thus, since a relatively large number of dies may be exposed to light in one shot in the first exposure process, a total number of shots required in the first exposure process for forming the pattern structure 52 on the entire substrate 50, i.e., both the die forming region and the edge die, may be relatively small.

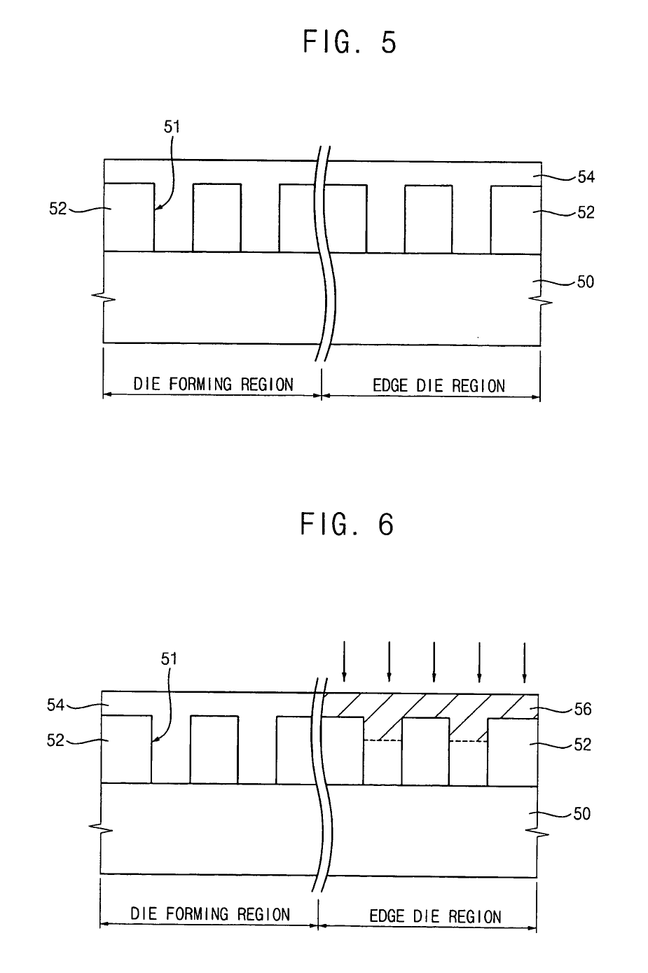

Referring to FIG. 5, a preliminary blocking layer 54 may be formed on the pattern structure 52. In particular, as illustrated in FIG. 5, the preliminary blocking layer 54 may fill the openings 51 by coating the substrate 50, and may coat an upper surface of the pattern structure 52. The preliminary blocking layer 54 may be formed on the entire substrate 50, i.e., both the die forming region and the edge die. The preliminary blocking layer 54 may be formed of a photosensitive composition including a siloxane polymer, a cross-linking agent, a photoacid generator, and a thermal acid generator. The photosensitive composition of the preliminary blocking layer 54 may be substantially the same as the photosensitive composition of the preliminary blocking layer 12 described previously with reference to FIGS. 1-3, and therefore, its detailed description will not be repeated.

Referring to FIG. 6, a portion of the preliminary blocking layer 54 in the edge die region of the substrate 50 may be exposed to light, i.e., the preliminary blocking layer 54 may be selectively exposed to light, in a second exposure process to form a first preliminary blocking pattern 56 in the edge die region of the substrate 50. A portion of the preliminary blocking layer 54 may remain in the die forming region of the substrate 50. The portion of the preliminary blocking layer 54 in the die forming region may be soluble in a developing solution used in a subsequent developing process, while the first preliminary blocking pattern 56 in the edge die region of the substrate 50 may be insoluble in the developing solution used in the subsequent developing process. The portion of the preliminary blocking layer 54 disposed in the edge die region of the substrate 50, i.e., a portion transformed into the first preliminary blocking pattern 56, may be exposed to light in the second exposure process using a second reticle defining at least one of second reticle images. Each second reticle image defined by the second reticle may correspond to a second number of dies. The second number of dies of each second reticle image may be at least one die and may be smaller than a first number of dies of the first reticle image in the first exposure process, i.e., each second reticle image of the second reticle may correspond to substantially fewer dies than the number of dies to which the reticle image defined by the first reticle corresponds.

As illustrated in FIG. 6, only an upper portion of the preliminary blocking layer 54 in the edge die region of the substrate 50 may be cured or cross-linked during the second exposure process to form the first preliminary blocking pattern 56 in the edge die region. Accordingly, an upper portion of the first preliminary blocking pattern 56 may be cured, and may cover the upper surface of the pattern structure 52 and a portion of the openings 51. A lower portion of the first preliminary blocking pattern 56 may not be cured and may be positioned in the openings 51, so the lower portion of the first preliminary blocking pattern 56 may be between the substrate 50 and the upper portion of the first preliminary blocking pattern 56. The upper portion of the first preliminary blocking pattern 56 may extend to a predetermined depth into the openings 51, i.e., a distance as measured from the upper surface of the pattern structure 52 toward the substrate 50 along a normal to the substrate 50.

Alternatively, an entire portion of the preliminary blocking layer 54 in the edge die region of the substrate 50 may be cured or cross-linked in the second exposure process to form the first preliminary blocking pattern 56 in the edge die region (not illustrated). In other words, both upper and lower portions of the first preliminary blocking pattern 56 in the edge die region of the substrate 50 may be cured by the second exposure process.

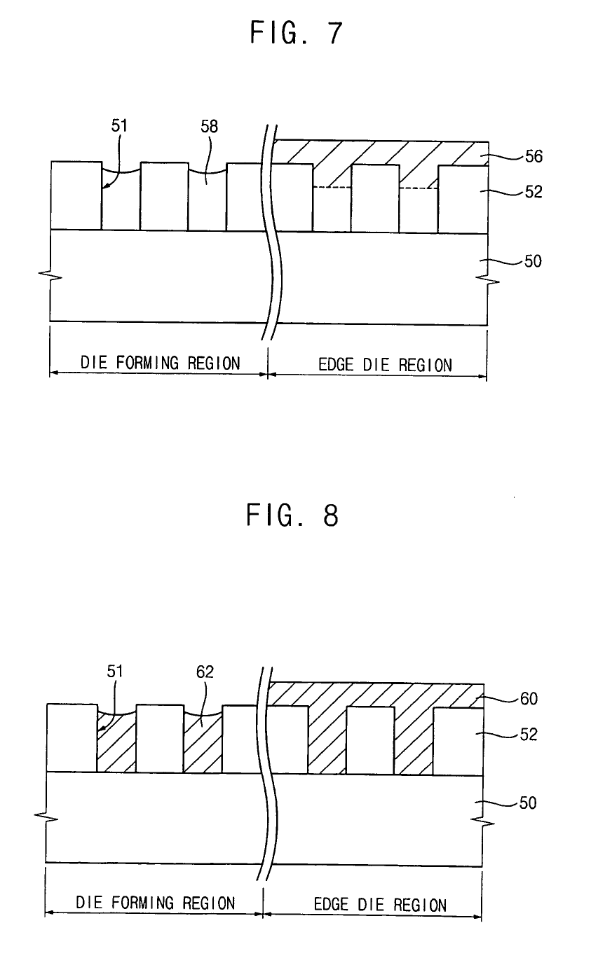

Once the blocking pattern 56 is formed on the substrate 50 in the edge die region thereof, the substrate 50 may be developed using a developing solution to remove at least a portion of the preliminary blocking layer 54 from the die forming region of the substrate 50. In particular, as illustrated in FIG. 7, an upper portion of the preliminary blocking layer 54 in the die forming region of the substrate 50 may be removed from the substrate 50, e.g., to expose the upper surface of the pattern structure 52 in the die forming region of the substrate 50, to form a second preliminary blocking pattern 58. The second preliminary blocking pattern 58 may be formed on the substrate 50, and may substantially fill the openings 51 in the die forming region of the substrate 50.

The second preliminary blocking pattern 58 may be formed by immersing the substrate 50 in the developing solution, so the preliminary blocking layer 54 may be partially removed in the die forming region of the substrate 50. A height of the second preliminary blocking pattern 58, i.e., a distance as measured from an upper surface of the second preliminary blocking pattern 58 to an upper surface of the substrate 50, may be adjusted by changing a length of time for immersing the substrate 50 in the developing solution. For example, as illustrated in FIG. 7, the height of the second preliminary blocking pattern 58 may be smaller than a height of the pattern structure 52. It is noted that since the blocking pattern 56 is insoluble in the developing solution, the blocking pattern 56 may remain in the edge die region of the substrate 50, as further illustrated in FIG. 7.

Referring to FIG. 8, the first preliminary blocking pattern 56 and the second preliminary blocking pattern 58 may be cured or cross-linked to form a first blocking pattern 60 and a second blocking pattern 62 on the substrate 50, respectively. The curing process may be performed by performing a thermal treatment. For example, when the thermal treatment is performed, an acid may be generated by the thermal acid generator in the photosensitive composition of the first preliminary blocking pattern 56 to accelerate a cross-linking reaction, so the first and second preliminary blocking patterns 56 and 58 may be substantially cured. For example, the curing process may be performed at a temperature of about 100° C. to about 300° C. It is noted that if only an upper portion of the first preliminary blocking pattern 56 is cured during the second exposure process described previously with reference to FIG. 6, the lower portion of the first preliminary blocking pattern 56 may be cured during the curing process, so the entire first preliminary blocking pattern 56 may be cured to form the first blocking pattern 60 in the edge die region of the substrate 50.

According to example embodiments, as illustrated in FIG. 8, the first blocking pattern 60 may be disposed in the edge die region of the substrate 50, and may substantially protect the edge die region of the substrate 50. The second blocking pattern 62 may be disposed in the die forming region, and may block at least a portion of the structure pattern 52, e.g., inner sidewalls and bottoms of the openings 51, in the die forming region of the substrate 50. As such, the first and second blocking patterns 60 and 62 may substantially cover an edge die region of a substrate and partially cover a die forming region of the substrate, respectively.

Method of Manufacturing a Semiconductor Device

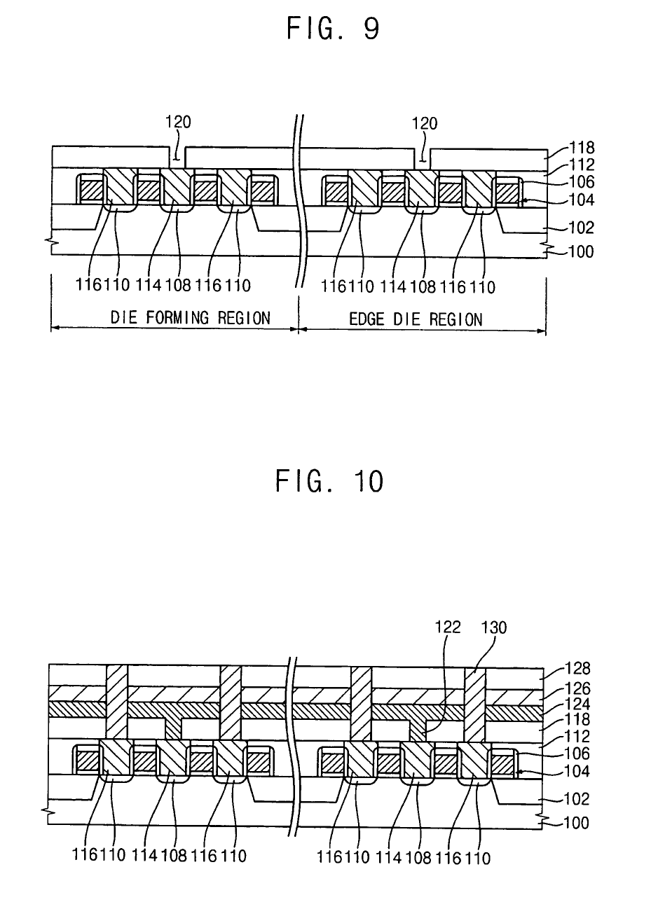

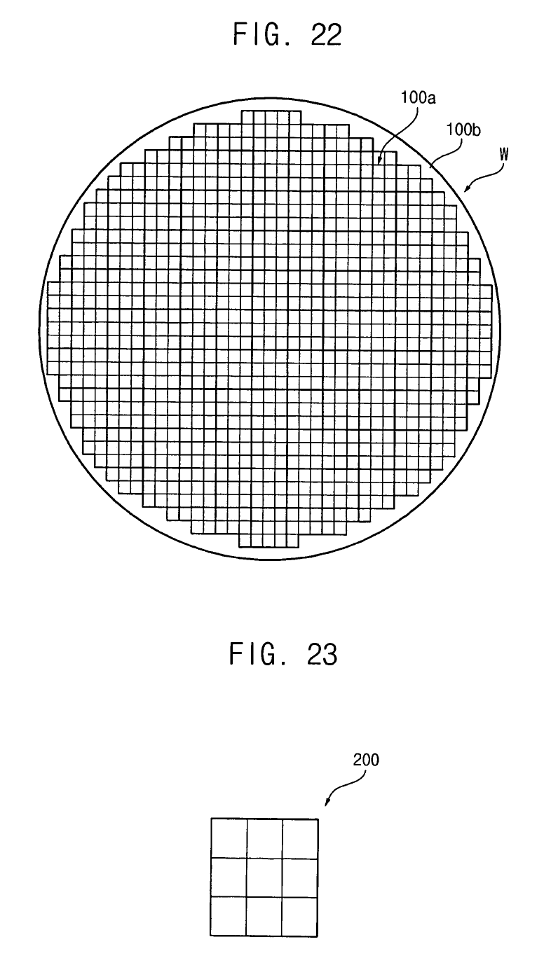

FIGS. 9-21 illustrate cross-sectional views of stages in a method of manufacturing a semiconductor device in accordance with some example embodiments. FIG. 22 illustrates a schematic diagram of a die forming region and an edge die region in a substrate of the semiconductor device formed according to FIGS. 9-21.

Referring to FIG. 9, a semiconductor substrate 100 having a die forming region and an edge die region may be prepared. The die forming region and the edge die region of the substrate 100 may be substantially same as the die forming region and the edge die region of the substrate 10 described previously with reference to FIGS. 1-3. In FIG. 22, reference numeral 100a indicates the die forming region, i.e., a region including a plurality of squares, and reference numeral 100b indicates the edge die region, i.e., a region surrounding the plurality of squares.

Referring to FIG. 9, a shallow trench isolation process may be performed on the semiconductor substrate 100 to form an isolation layer 102 on the semiconductor substrate 100. As a result, the semiconductor substrate 100 may be divided into active regions and field regions. The active region may extend along a first direction, so a length of the active regions may be measured along a lengthwise direction of the active region.

A transistor associated with a word line may be formed on the semiconductor substrate 100. In an exemplary formation method of the transistor, a gate oxide layer (not illustrated) may be formed on the semiconductor substrate 100 in the active region, followed by formation of a first conductive layer (not illustrated) and a first hard mask layer (not illustrated) on the gate oxide layer. The first conductive layer may function as a gate electrode, and may be formed, e.g., of one or more of polysilicon doped with impurities, tungsten, and tungsten silicide.

The first hard mask layer may be patterned through a photolithography process to form a first hard mask pattern. The first conductive layer may be etched using the first hard mask pattern as an etching mask to form the gate electrode. The gate electrode may have a line shape, and may extend along a second direction, i.e., a direction perpendicular to the first direction. As a result, a gate structure 104 including the gate oxide layer, the gate electrode, and the first hard mask pattern may be formed on the semiconductor substrate 100. It is noted that multiple gate structures 104 may be formed on the substrate 100 by a substantially same process as described above.

Once the gate structure 104 is formed, an insulation layer (not illustrated) may be formed on the semiconductor substrate 100 of, e.g., a silicon nitride. The insulation layer may be anisotropically etched to form first spacers 106 on sidewalls of the gate structure 104, as illustrated in FIG. 9.

An ion implantation process may be performed using the gate structures 104 and the first spacers 106 as a mask to implant impurities into portions of the semiconductor substrate 100 between adjacent gate structures 104. As a result, as illustrated in FIG. 9, source regions 108 and drain regions 110 may be formed in upper portions of the semiconductor substrate 100 to complete formation of the transistor associated with the word line on the substrate 100.

Once the transistor is formed, a first insulating interlayer 112 may be formed to cover the transistor. The first insulating interlayer 112 may be formed using silicon oxide, e.g., one or more of borophosphosilicate glass (BPSG), phosphosilicate glass (PSG), undoped silicate glass (USG), spin-on-glass (SOG), plasma-enhanced tetraethyl orthosilicate (PE-TEOS), and high-density plasma chemical vapor deposition (HDP-CVD) oxide. The first insulating interlayer 112 may be formed by, e.g., a chemical vapor deposition (CVD) process, a plasma-enhanced chemical vapor deposition (PECVD) process, a high-density plasma chemical vapor deposition (HDPCVD) process, or an atomic layer deposition (ALD) process. Once the first insulating interlayer 112 is formed, a chemical mechanical polishing (CMP) process may be performed to remove an upper portion of the first insulating interlayer 112, i.e., planarize an upper surface of the first insulating interlayer 112.

A photoresist pattern (not illustrated) may be formed on the first insulating interlayer 112, and the first insulating interlayer 112 may be etched using the photoresist pattern as an etching mask to form first contact holes (not shown) therethrough to expose source regions 108 and drain regions 110. The first contact holes may be formed through the first insulating interlayer 112 by self-alignment relative to the first spacers 106 disposed on sidewalls of the gate structures 104. The photoresist pattern may be removed from the semiconductor substrate 100 by at least one of an ashing process and a striping process.

A second conductive layer (not illustrated) may be formed on the first insulating interlayer 112 to fill the first contact holes. The second conductive layer may be formed from, e.g., polysilicon doped with impurities. An upper portion of the second conductive layer disposed on the first insulating interlayer 112 may be removed, e.g., by a CMP process, to expose an upper surface of the first insulating interlayer 112, so portions of the second conductive layer may remain in the first contact holes to define contact plugs in the first contact holes. Each one of the contact plugs may be electrically connected to one of source regions 108 or to one of drain regions 110. A contact plug making contact with one of the source regions 108 may be referred to hereinafter as a first contact plug 114, and a contact plug making contact with one of the drain regions 110 may be referred to hereinafter as a second contact plug 116. Each first contact plug 114 may be connected to a bit line, and each second contact plug 116 may be connected to a capacitor.

A second insulating interlayer 118 may be formed on the first insulating interlayer 112. The second insulating interlayer 118 may be formed using, e.g., silicon oxide. A photoresist pattern (not illustrated) may be formed on the second insulating interlayer 118. As illustrated in FIG. 9, the second insulating interlayer 118 may be etched using the photoresist pattern as an etching mask to form second contact holes 120 exposing the first contact plugs 114.

Referring to FIG. 10, a third conductive layer (not illustrated) may be formed on the second insulating interlayer 118 to cover an upper surface of the second insulating layer 118 and to fill the second contact holes 120. A second hard mask layer (not illustrated) may be formed, e.g., of silicon nitride, on the third conductive layer. For example, the third conductive layer may have a stacked structure including a barrier metal layer, e.g., a titanium/titanium nitride layer, and a metal layer, e.g., a tungsten layer.

A photoresist pattern (not illustrated) may be formed on the second hard mask layer. The second hard mask layer may be etched using the photoresist pattern as an etching mask to form a second hard mask pattern 126 on the third conductive layer, followed by removal of the photoresist pattern from the second hard mask pattern 126.

The third conductive layer may be patterned using the second hard mask pattern 126 as an etching mask to form a bit line 124. The bit line 124 may include bit line contacts 122 filling the second contact holes 120, so each bit line contact 122 may connect a corresponding first contact plug 114 to the bit line 124. The bit line 124 may extend along the first direction, i.e., perpendicularly to the direction of the gate structure 104. A silicon nitride layer (not illustrated) may be formed on the bit line 124, second hard mask pattern 126, and second insulating interlayer 118, followed by anisotropic etching of the silicon nitride layer to form second spacers (not illustrated) on sidewalls of the bit line 124 and on the second hard mask pattern 126.

A third insulating interlayer 128 may be formed on the second insulating interlayer 118 and on the bit line 124. The third insulating interlayer 128 may be formed using, e.g., silicon oxide. A CMP process may be performed to planarize an upper surface of the third insulating interlayer 128. A photoresist pattern (not illustrated) may be formed on the third insulating interlayer 128, so the third insulating interlayer 128 and the second insulating interlayer 118 may be etched using the photoresist pattern as an etching mask to form third contact holes (not shown) exposing second contact plugs 116. The third contact holes may be formed through self-alignment relative to the second spacers formed on the sidewalls of the bit line 124 and the second hard mask pattern 126.

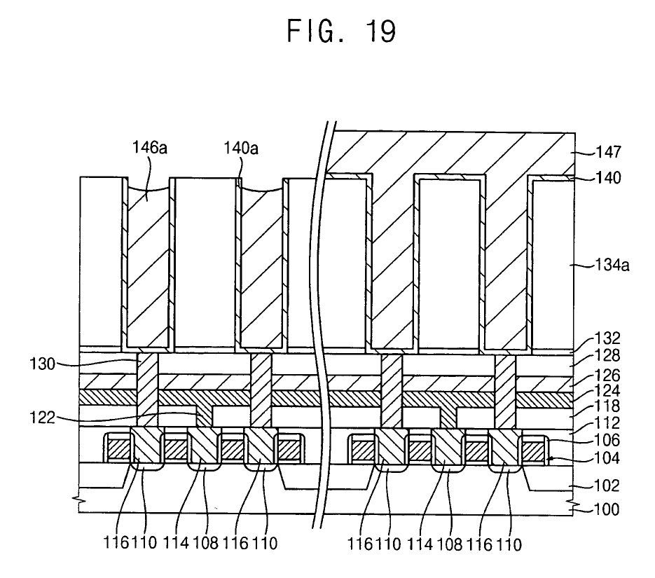

A third conductive layer (not illustrated) may be formed on the third insulating interlayer 128 to fill the third contact holes. The third conductive layer may be formed using polysilicon doped with impurities. An upper portion of the third conductive layer may be removed, e.g., by performing a CMP process, to form third contact plugs 130 in the third contact holes, so the third contact plugs 130 may connect the second contact plugs 116 to lower electrodes 140a formed in a subsequent process (see FIG. 19). The third contact plugs 130 may be disposed partially in the third insulating interlayer 128.

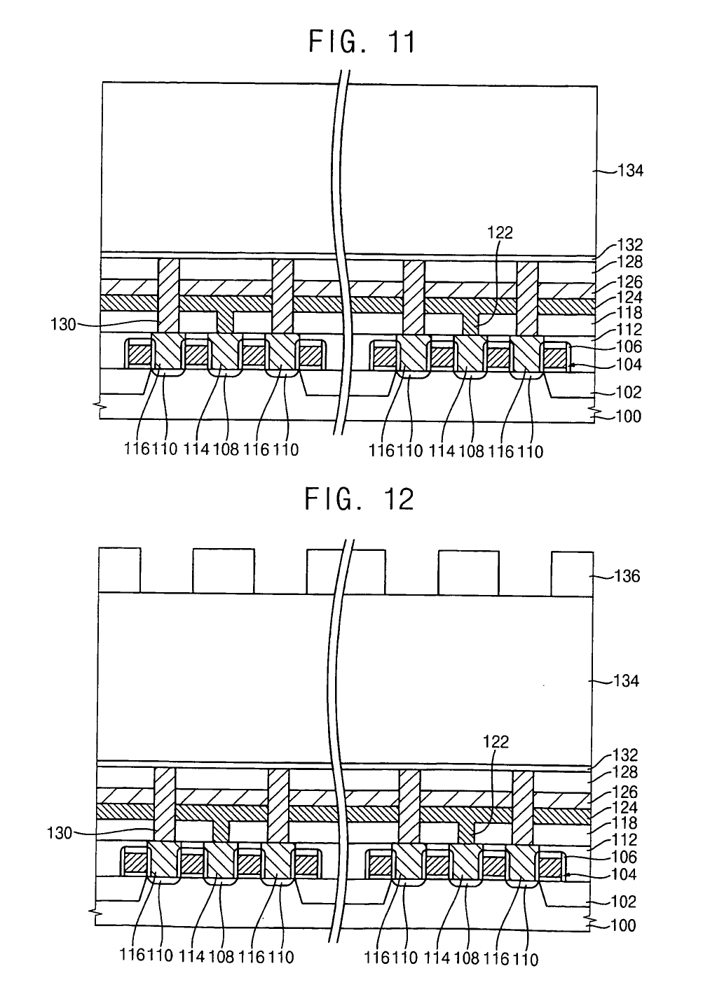

Referring to FIG. 11, an etch stop layer 132 may be formed on the third insulating interlayer 128 and on the third contact plugs 130. For example, the etch stop layer 132 may be formed using silicon nitride. In an example embodiment, a buffer oxide layer (not illustrated) may be formed between the etch stop layer 132 and the third insulating interlayer 128, i.e., the buffer oxide layer may separate between the etch stop layer 132 and the third insulating interlayer 128 and between the etch stop layer 132 and the third contact plugs 130.

A mold oxide layer 134 may be formed on the etch stop layer 132. The mold oxide layer 134 may be formed by depositing an oxide, e.g., one or more of borophosphosilicate glass (BPSG), phosphosilicate glass (PSG), undoped silicate glass (USG), spin-on-glass (SOG), plasma enhanced-tetraethyl orthosilicate (PE-TEOS), etc. The mold oxide layer 134 may function as a template for forming lower electrodes 140a, and may be formed to have a substantially larger thickness, e.g., a distance as measured from an upper surface of the mold oxide layer 134 to an upper surface of the etch stop layer 132, than a height of the lower electrodes 140a to be formed subsequently.

Referring to FIG. 12, a photoresist film (not illustrated) may be formed on the mold oxide layer 134 by coating the mold oxide layer 134 with a photoresist composition. A first exposure process may be performed on the photoresist film on the entire substrate 100, i.e., both die forming region and edge die region, using a first reticle defining a first reticle image. The first reticle defining the first reticle image may be used to expose a predetermined region of the photoresist film to light, e.g., selectively expose the photoresist film to light, so the predetermined region of the photoresist film exposed to light may be in the die forming region and in the edge die region. The lower electrode may be formed in the predetermined region.

It is noted that the first reticle image defined by the first reticle may correspond to a maximum number of dies or chips that may be exposed through a single shot of light. Thus, a number chips that may be exposed to light through a single shot using the first reticle according to example embodiments may be relatively large. For example, as illustrated in FIG. 23, the first reticle image defined by the first reticle may correspond to nine chips, so nine chips may be exposed through a single shot in the first exposure process. Since a relatively large number of chips may be exposed in a single shot in the first exposure process, a relatively small number of shots may be required to expose the photoresist film on the entire substrate 100.

In contrast, in a conventional exposure process for patterning a mold oxide layer, exposure of a film only within the die forming region of the substrate, e.g., exposure in an edge die region may be minimized to reduce shifting or removal of abnormal lower electrodes in the edge die region of the substrate, may be controlled by using a reticle defining reticle images corresponding to a relatively small number of chips, e.g., one, two, or three chips. Accordingly, a relatively large number of shots may be required to sufficiently expose the film in the die forming region.

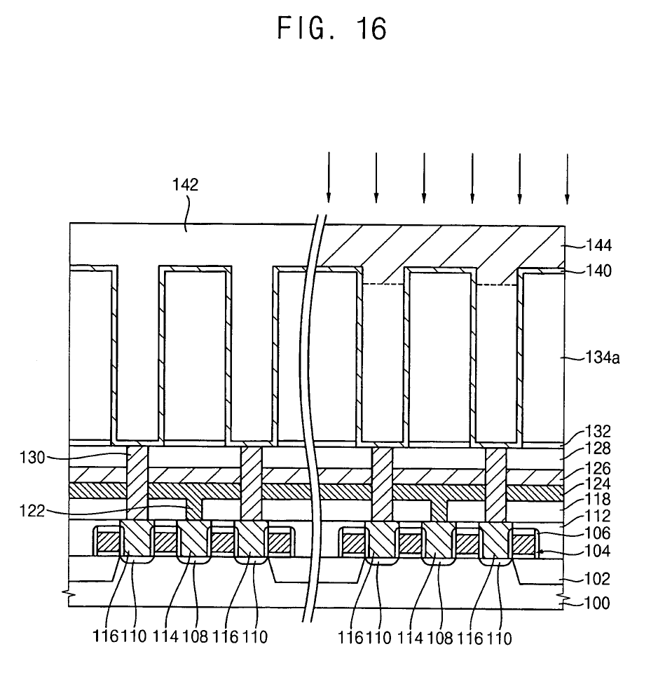

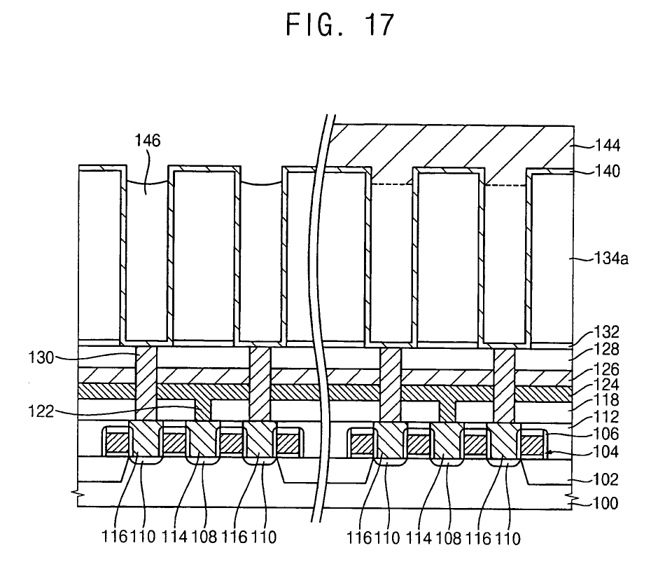

Therefore, the reticle image defined by the first reticle according to embodiments of the present invention may require only a single type of reticle image that corresponds to a larger number of chips than the conventional process, so the number of shots and the processing time required for patterning the mold oxide layer 134 may be substantially reduced. Therefore, manufacturing productivity according to example embodiments may be improved. Further, portions of the photoresist film disposed in the edge die region of the substrate 100 and exposed to light due to a relatively large number of chips defined by the reticle image, may not be shifted and/or removed due to the protection layer. Accordingly, removal or shifting of portions of lower electrodes formed in the edge die region may be prevented or substantially minimized by forming a blocking layer 144 in the edge die region of the substrate 50 in a subsequent process (See FIG. 16).

After the first exposure process of the photoresist film is complete, a developing process and a baking process may be performed on the photoresist film to form a photoresist pattern 136 on the mold oxide layer 134. The photoresist pattern 136 may be formed in the edge die region and in the die forming region of the substrate 100.

In another example embodiment, a hard mask layer (not illustrated) may be formed on the mold oxide layer 134. The photoresist pattern 136 may be formed on the hard mask layer through processes that may be substantially the same as those described above. Then, the hard mask layer may be etched using the photoresist pattern 136 to form a hard mask pattern (not illustrated) on the mold oxide layer 134. The hard mask pattern may be formed in the edge die region as well as in the die forming region. The hard mask pattern may be used as an etching mask in a process for patterning the mold oxide layer 134.

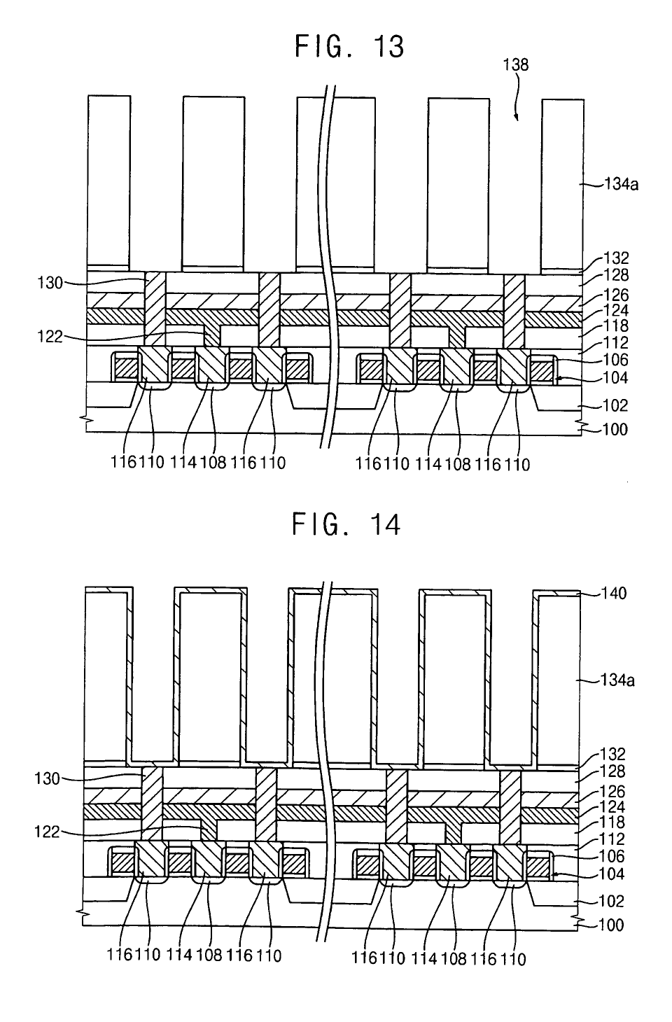

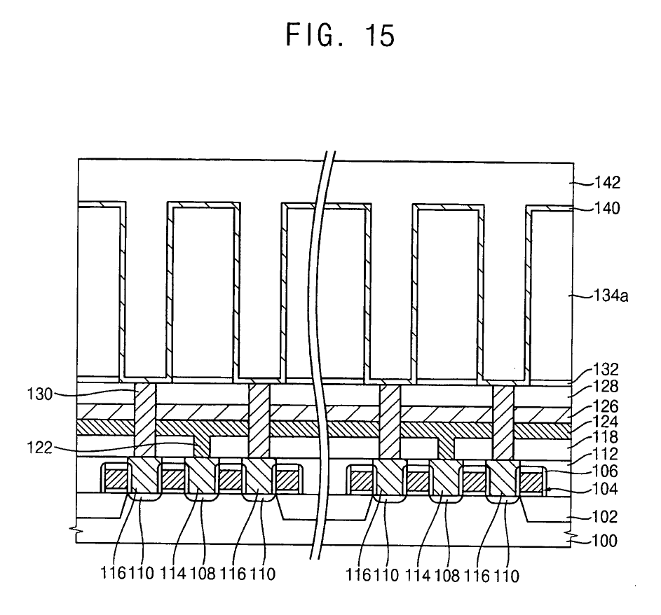

Referring to FIG. 13, portions of the mold oxide layer 134 and of the etch stop layer 132 may be etched using the photoresist pattern 136 as an etching mask to form a mold oxide layer pattern 134a on the third insulating interlayer 128. The etched mold oxide layer 134 and etch stop layer 132 may define openings 138, so each opening 138 may expose an upper surface of a corresponding third contact plug 130. The openings 138 and the mold oxide layer pattern 134a may be formed in the edge die region and in the die forming region of the substrate 100, and may function as a template for forming the lower electrodes 140a in a subsequent process. The photoresist pattern 136 may be removed from the mold oxide layer pattern 134a.

Referring to FIG. 14, a lower electrode layer 140 may be conformally formed on the mold oxide layer pattern 134a, i.e., on sidewalls and bottoms of the openings 138 and on an upper surface of the mold oxide layer pattern 134a. A lower electrode layer 140 may be formed using one or more of a metal, a metal nitride, and a semiconductor doped with impurities. For example, the lower electrode layer 140 may be formed using one or more of polysilicon doped with impurities, titanium (Ti), titanium nitride (TiN), etc. When the lower electrode layer 140 is formed using only one type of a conductive material, the lower electrode layer 140 may have a single layer structure. When conductive layer 140 is formed using two or more types of conductive materials, the lower electrode layer 140 may have a multi-layered structure.

In one example embodiment, the lower electrode layer 140 may be formed using a metal or a metal nitride to form a capacitor occupying a relatively small area and having a relatively high storage capacitance. In another example embodiment, the lower electrode layer 140 may be formed using polysilicon doped with impurities to improve step coverage of the lower electrode layer 140, despite a depletion layer generated between a dielectric layer and a subsequently formed lower electrode. In still another example embodiment, the lower electrode layer 140 may be a multi-layer of titanium and titanium nitride. In that embodiment, the titanium of the lower electrode layer 140, which may make direct contact with one of the third contact plugs 130, may be converted into titanium silicide through a reaction between the titanium and polysilicon of the third contact plug 130. The titanium silicide layer formed through that reaction may function as an ohmic layer.

Referring to FIG. 15, a preliminary blocking layer 142 may be formed on the lower electrode layer 140, and may fill the openings 138, i.e., the preliminary blocking layer 142 may fill portions of the openings 138 not filled by the lower electrode layer 140. The preliminary blocking layer 142 may be formed in the die forming region and the edge die region of the substrate 100. The preliminary blocking layer 142 may be formed by coating, e.g., spin-coating, the lower electrode layer 140 with a photosensitive composition. The photosensitive composition may include a siloxane polymer, a cross-linking agent, a thermal acid generator and a photoacid generator. The photosensitive composition of the preliminary blocking layer 142 may be substantially the same as the photosensitive composition of the preliminary blocking layer 12 described previously with reference to FIGS. 1-3, and therefore, its detailed description will not be repeated.

Use of the photosensitive composition in the preliminary blocking layer 142 may facilitate curing of the preliminary blocking layer 142 by an exposure process and/or a thermal treatment process. Further, use of the photosensitive composition may facilitate removal of the photosensitive composition, e.g., by a developing solution, prior to the exposure process or the thermal treatment process, and may facilitate removal of the cured photosensitive composition by a wet process using an etching solution that may include a fluoride compound instead of an ashing process.

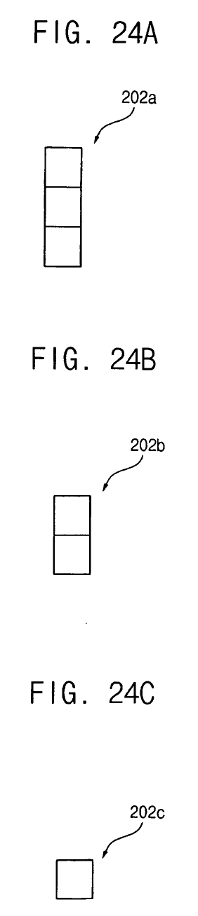

Referring to FIG. 16, the portion of the preliminary blocking layer 142 disposed in the edge die region may be exposed to light, i.e., the preliminary blocking layer 142 may be selectively exposed to light. A second exposure process may be performed using a second reticle defining multiple reticle images. Each reticle image defined by the second reticle may correspond to one or more dies, i.e., may correspond to substantially fewer than a maximum number of dies that may be exposed in a single shot of light. For example, as shown in FIGS. 24A-24C, a reticle image defined by the second reticle may correspond to one, two, or three dies or chips.

A portion of the preliminary blocking layer 142 disposed in the edge die region and exposed to light in the second exposure process may be cured through a cross-linking reaction activated by an acid generated from the photoacid generator. Thus, the exposed portion of the preliminary blocking layer 142 in the edge die region may be altered to become insoluble in the developing solution. As a result, a first preliminary blocking pattern 144 having a cured portion may be formed in the edge die region of the substrate 100. In one embodiment, only an upper portion of the preliminary blocking layer 142 disposed in the edge die region may be converted into the first preliminary blocking pattern 144, as illustrated in FIG. 16. In another embodiment, an entire portion of the preliminary blocking layer 142 disposed in the edge die region may be converted into the first preliminary blocking pattern 144, e.g., first preliminary blocking pattern 144 that completely fills the openings 138.

It is noted that the second exposure process may be performed to expose an entire edge die region of the substrate 100 to trigger a cross-linking reaction and not for forming a fine pattern in the edge die region. Thus, the second exposure process may not require an exposure apparatus with a relatively high resolution. Rather, the second exposure process may be performed using an exposure apparatus having a relatively low resolution, i.e., having a relatively low grade. For example, the second exposure process may be performed using an I-line exposure apparatus, a KrF exposure apparatus or an ArF exposure apparatus.

Referring to FIG. 17, an upper portion of the preliminary blocking layer 142 disposed in the die forming region may be removed using a developing solution. In an example embodiment, a developing process having an appropriate developing time and concentration rate may be performed to remove a portion of the preliminary blocking layer 142 disposed on the upper surface of the mold oxide layer pattern 134a in the die forming region, i.e., to selectively remove a portion of the preliminary blocking layer 142 in the die forming region. After the upper portion of the preliminary blocking layer 142 disposed in the die forming region is removed, other portions, e.g., a lower portion, of the preliminary blocking layer 142 may remain in the die forming region and may form a second preliminary blocking pattern 146 in the opening 138 in the die forming region of the substrate 100. While the developing process is performed, the first preliminary blocking pattern 144 disposed in the edge die region may not be dissolved in the developing solution.

The developing process may be performed using a developing solution used in the development of photoresist. For example, the developing solution may include about 2.4 percent by weight of tetramethylammonium hydroxide and about 97.6 percent by weight of water.

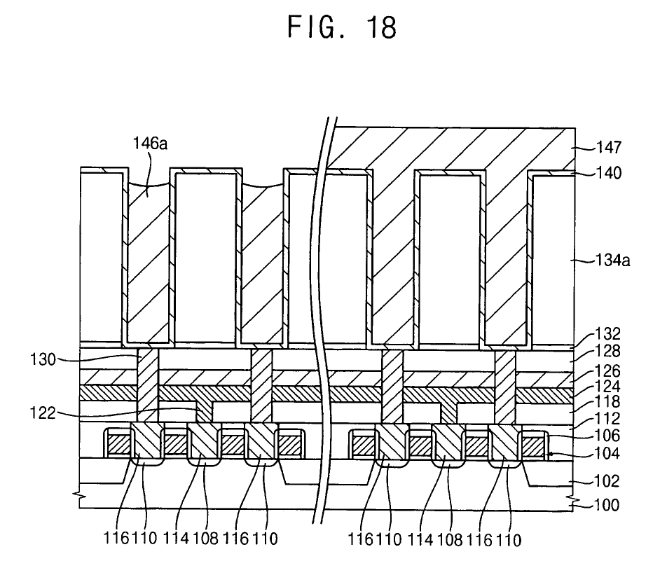

Referring to FIG. 18, the first preliminary blocking pattern 144 and the second preliminary blocking pattern 146 may be cured through a thermal treatment to form a first blocking pattern 147 and a second blocking pattern 146a, respectively. The first and second preliminary blocking patterns 144 and 146 may include the thermal acid generator and the cross-linking agent, so the first and the second preliminary blocking patterns 144 and 146 may be cured by a cross-linking reaction activated by acid generated during the thermal treatment. The thermal treatment may be performed at a temperature of about 100° C. to about 300° C. to improve etching resistance of the first and the second blocking patterns 147 and 146a.

Referring to FIG. 19, upper portions of the lower electrode layer 140 on the mold layer pattern 134a in the die forming region may be removed. As an example, the removal process may be performed using an etch-back process. When a blanket etching process is performed without using a mask pattern, the exposed upper portions of the lower electrode layer 140 in the die forming region may be etched, while portions of the lower electrode layer 140 in the edge die region may be protect by the first blocking pattern 147 and may remain unetched. As a result, portions of the lower electrode layer 140 formed on sidewalls and bottoms of the opening 138 in the die forming region of the substrate 100 may remain on the semiconductor substrate 100 to form the lower electrodes 140a, and portion of the lower electrode layer 140 under the first blocking pattern 147 may remain in the edge die region unetched. That is, the lower electrodes 140a may be formed in the die forming region by etching the exposed upper portions of the lower electrode layer 140 in the die forming region. For example, the lower electrodes 140a in the die forming region may have a cylindrical shape.

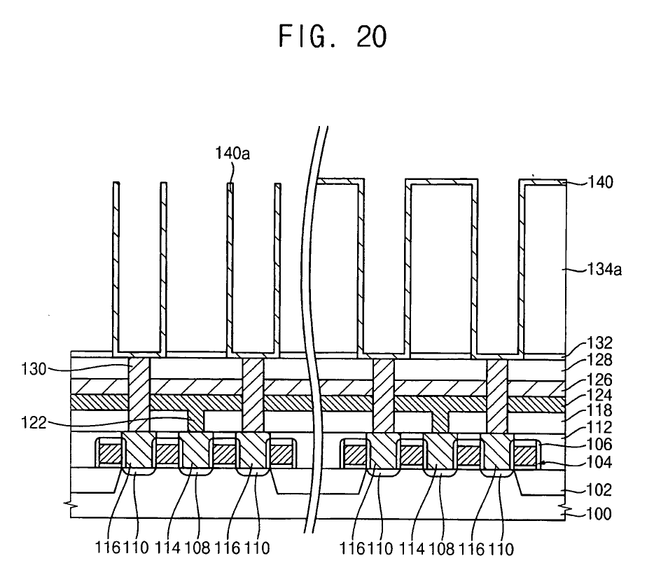

After forming the lower electrodes 140a in the die forming region, a cleaning process may be performed to remove etching residue from the lower electrodes 140a. Referring to FIG. 20, an etching process may be performed on the semiconductor substrate 100 to remove the mold oxide layer pattern 134a in the die forming region, and the first and the second blocking patterns 147 and 146a. The etching process may be a wet etching process using an etching solution. In an example embodiment, the etching solution may include a fluoride compound, e.g., one or more of hydrogen fluoride, ammonium fluoride, ammonium bifluoride, sodium fluoride, sodium hydrogen fluoride, barium fluoride, potassium fluoride, ammonium fluoroborate, etc. For example, the etching solution may be an LAL solution including hydrogen fluoride, ammonium fluoride and water.

In contrast, in a conventional method of forming a blocking pattern using a photoresist having an organic polymer, e.g., a methacrylate-based resin, the blocking pattern may not be readily removed by a wet etching process, thereby requiring use of an ashing process using plasma. The ashing process may cause severe damage to a lower electrode which may be exposed to plasma during the removal of the blocking pattern and may also generate polymeric contaminants that may not be easily removed from a semiconductor substrate. Example embodiments of the present invention, however, may include formation of the first and the second blocking patterns 147 and 146a of siloxane polymer, so the first and the second blocking patterns 147 and 146a may be substantially completely removed from the substrate 100 using a wet etching solution including, e.g., a fluoride compound. The wet etching solution used in removing the first and the second blocking patterns 147 and 146a may not substantially cause damage (e.g., plasma damage) to the lower electrode.

Further, the first and the second blocking patterns 147 and 146a and the mold oxide layer pattern 134a in the die forming region may be removed by the same etching process. Thus, a processing time for removing the first and the second blocking patterns 147 and 146a and the mold oxide layer pattern 134a in the die forming region may be substantially reduced, and process efficiency may be substantially improved. Further, the first and the second blocking patterns 147 and 146a having the siloxane polymer may have high solubility relative to the wet etching solution including, e.g., a fluoride compound, and thus may be readily removed during the wet etching process. Accordingly, generation of polymeric contaminants may be prevented or substantially minimized while the first and second blocking patterns 147 and 146a are removed, so defects in the semiconductor device may be substantially reduced.

By removing the mold oxide layer pattern 134a and the second blocking pattern 146a from the die forming region, a bottom, inner walls and outer walls of the lower electrode 140a may be exposed in the die forming region. In addition, a portion of the lower electrode layer 140 disposed in the edge die region may be exposed by removing the first blocking pattern 147 from the edge die region. The portion of the lower electrode layer 140 disposed in the edge die region may be continuously formed because the portion of the lower electrode layer 140 disposed under the first blocking pattern 147 may remain in the edge die region unetched. Thus, shifting or removing of the lower electrode layer 140 in the edge die region of the substrate 100 during formation of the lower electrodes 140a in the die forming region of the substrate 100 may be prevented or substantially minimized.

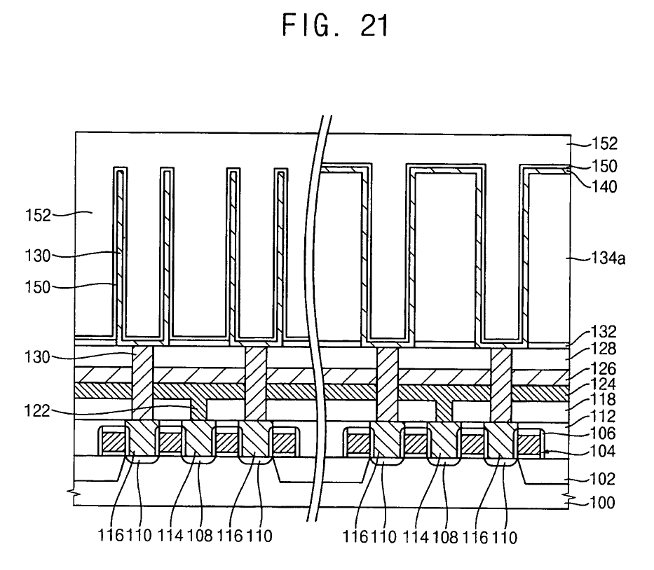

Referring to FIG. 21, a dielectric layer 150 may be formed on the lower electrodes 140a in the die forming region and on a portion of the lower electrode layer 140 in the edge die region. The dielectric layer 150 may be formed using silicon oxide, an oxide-nitride stack, an oxide-nitride-oxide, or a metal oxide. For example, the dielectric layer 150 may be formed using a metal oxide having a relatively thin equivalent oxide thickness and relatively good leakage current characteristics.

An upper electrode 152 may be formed on the dielectric layer 150. The upper electrode 152 may be formed using one or more of polysilicon doped with impurities, a metal, a metal nitride, etc. The upper electrode 152 may include a material having a metal to improve a storage capacitance of a capacitor. In addition, the upper electrode 152 may, for example, be formed having a multi-layered structure including a titanium nitride film and a doped polysilicon film.

The dielectric layer 150 and the upper electrode 152 may be sequentially formed on the lower electrodes 140a to complete the formation of capacitors electrically connected to the third contact plugs 130.

### EXAMPLES

A number of shots required for forming a lower electrode in accordance with an example embodiment was compared with a number of shots required for forming a lower electrode using a conventional method, i.e., using a conventional reticle defining reticle images corresponding to fewer than a maximum number of chips that may be exposed in one shot when forming a mold layer pattern.

### Example 1

A hard mask pattern was used to form a mold layer pattern according to an example embodiment, and a first reticle defining a reticle image was used in a first exposure process according to an example embodiment. As illustrated in FIG. 22, the substrate W included a die forming region 100a and an edge die region 100b surrounding the die forming region 100a. The reticle image defined by the first reticle corresponded to nine chips, i.e., nine dies, as illustrated in FIG. 23, so nine chips was the maximum number of chips exposed to light in a single shot according to an example embodiment. The first reticle illustrated in FIG. 23 was a single reticle used to expose substrate W illustrated in FIG. 22 to light.

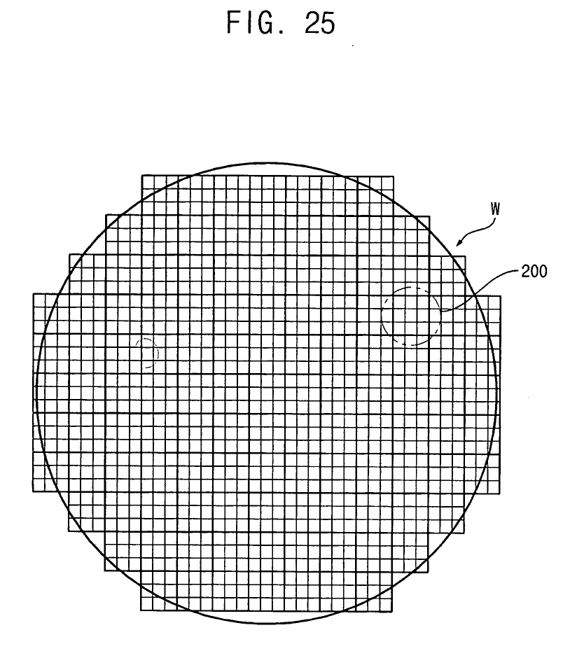

As illustrated in FIG. 25, after exposing the entire substrate W to light, since a reticle image 200 corresponded to a relatively large number of chips, i.e., nine chips illustrated in FIG. 23, the first exposure process was performed in the die forming region 100a of the substrate W and in the edge die region 100b of the substrate W. A number of shots used in the first exposure process for exposing the substrate W of FIG. 25 to light was 119.

### Example 2

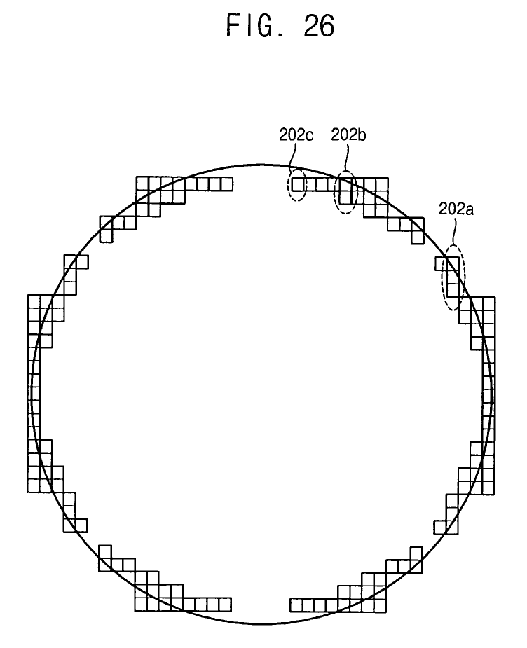

In accordance with an example embodiment, only the edge die region 100b of the substrate W was additionally exposed to light in a second exposure process. A second reticle defining three types of reticle images, as illustrated in FIGS. 24A, 24B, and 24C, was used in the second exposure process. In particular, the second reticle defined a reticle image 202a corresponding to three chips, a reticle image 202b corresponding to two chips, and a reticle image 202c corresponding to one chip. The edge die region 100b of the substrate W was selectively exposed to light using the second reticle, as illustrated in FIG. 26, and the number of shots used in the second exposure process was about 74. Accordingly, a total number of shots used in the first and second exposure processes, i.e., a total number of shots used in examples 1-2, was 193.

### Comparative Example 1

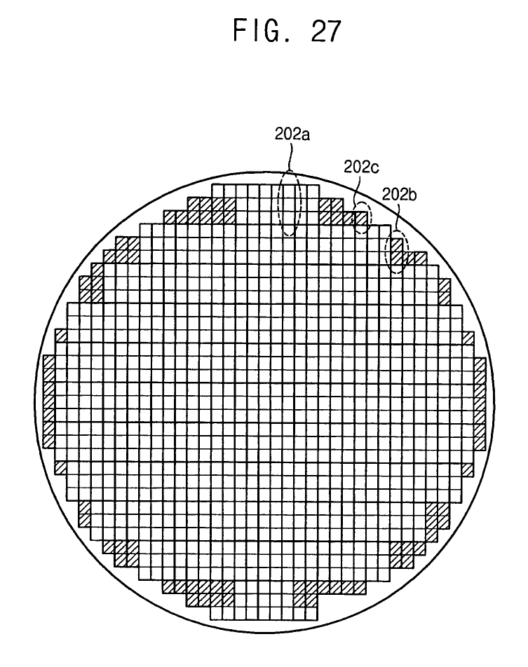

an exposure process for forming a mold layer pattern was performed using a reticle defining varying reticle images. The reticle used in the exposure process defined three types of reticle images, i.e., reticle images 202a-202c illustrated in FIGS. 24A-24C. In accordance with the conventional method, a number of chips exposed to light in one shot was reduced to one-third, as compared to a number of chips exposed to light in Example 1. The exposed substrate is illustrated in FIG. 27. Further, a number of shots required to expose the entire substrate W to light was about 331.

It is noted that a number of shots required to perform the first exposure process on the entire substrate W according to embodiments of the present invention, i.e., substrate W in FIG. 25, was reduced by more than about 50 percent as compared to the conventional method used to expose the substrate in FIG. 27. Further, a number of shots required to perform the first and second exposure processes of the substrate W according to embodiments of the present invention, i.e., substrate W in FIGS. 25 and 26, was smaller by about 40 percent as compared to the number of shots used in a single exposure process of the conventional method. It is further noted that in Examples 1-2, the second exposure process was performed using an inexpensive exposure apparatus having a relatively low grade, so, in addition to improving manufacturing productivity, manufacturing costs were reduced.

According to example embodiments, a blocking pattern may be readily formed using a negative-type photosensitive composition having a siloxane polymer to selectively cover or block a specific region, e.g., an edge die region, of a substrate. Accordingly, shifting or removing a lower electrode which may be disposed in the edge die region may be prevented. Further, the blocking pattern and a mold layer pattern may be simultaneously removed using a wet etching solution, thereby simplifying a semiconductor manufacturing process and reducing costs thereof. Damage or deterioration of the lower electrode, which may be caused by an ashing process performed for removing a conventional blocking pattern having organic photoresist, may be prevented, and generation of polymeric contaminants may be greatly suppressed and reduced. Therefore, efficiency and productivity of the semiconductor manufacturing process may be substantially improved.

Example embodiments of the present invention have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A method of forming a blocking pattern, comprising:
forming a preliminary blocking layer on first and second regions of a substrate, the preliminary blocking layer being formed of a photosensitive composition including a siloxane polymer, a cross-linking agent, a photoacid generator, and a thermal acid generator;
selectively exposing to light a first portion of the preliminary blocking layer, the first portion of the preliminary blocking layer being formed on the first region of the substrate, such that a cross-linked pattern is formed on the first region of the substrate; and
removing a second portion of the preliminary blocking layer, the second portion of the preliminary blocking layer being formed on the second region of the substrate.

2. The method as claimed in claim 1, wherein the first region of the substrate includes an edge die region, and the second region of the substrate includes a die forming region.

3. The method as claimed in claim 1, further comprising curing the preliminary blocking layer after removing the second portion of the preliminary blocking layer from the second region, curing the preliminary blocking layer including performing a thermal treatment process.

4. The method as claimed in claim 3, wherein removing the second portion of the preliminary blocking layer includes completely removing the preliminary blocking layer from the second region of the substrate, such that only the cross-linked pattern on the first region of the substrate is cured by the thermal treatment process.

5. The method as claimed in claim 3, wherein removing the second portion of the preliminary blocking layer includes partially removing the preliminary blocking layer from the second region of the substrate to form a partial layer on the second region of the substrate, such that both the cross-linked pattern on the first region and the partial layer on the second region are cured by the thermal treatment process.

6. The method as claimed in claim 1, wherein removing the second portion of the preliminary blocking layer from the second region is performed by a developing process.

7. The method as claimed in claim 1, wherein the photosensitive composition comprises about 0.1 parts to about 20 parts by weight of the cross-linking agent, about 0.01 parts to about 20 parts by weight of the photoacid generator, and about 0.01 parts to about 20 parts by weight of the thermal acid generator, based on about 100 parts by weight of the siloxane polymer.

8. The method as claimed in claim 1, wherein the photosensitive composition comprises a siloxane polymer including silicon-oxygen bonds in a backbone and at least one labile group substituent, the labile group being an acid-labile group and/or a heat-labile group.

9. A method of forming a blocking pattern, comprising:
forming a pattern structure with openings on a substrate, the substrate including a die forming region and an edge die region;
forming a preliminary blocking layer on the pattern structure to fill the openings, forming the preliminary blocking layer including coating a photosensitive composition on the pattern structure, the photosensitive composition including a siloxane polymer, a cross-linking agent, a photoacid generator, and a thermal acid generator;
selectively exposing to light a first portion of the preliminary blocking layer to form a first preliminary blocking pattern on the pattern structure in the edge die region of the substrate, the first preliminary blocking pattern including a cross-linked portion;
removing a second portion of the preliminary blocking layer, the second portion of the preliminary blocking layer being formed in the die forming region of the substrate, such that a second preliminary blocking pattern is formed in the openings of the pattern structure in the die forming region of the substrate; and
curing the first and the second preliminary blocking patterns to form a first blocking pattern in the edge die region and a second blocking pattern in the die forming region.

10. The method as claimed in claim 9, wherein forming the pattern structure on the substrate includes:
forming a layer on the substrate;
forming a photoresist film on the layer;
forming a photoresist pattern on the layer by performing an exposure process on the photoresist film using a first reticle, the first reticle defining a first reticle image corresponding to a first number of dies; and
etching the layer using the photoresist pattern as an etching mask to form the pattern structure on the substrate.

11. The method as claimed in claim 10, wherein selectively exposing to light the preliminary blocking layer includes using a second reticle, the second reticle defining a second reticle image corresponding to a second number of dies, the second number of dies being larger than zero and smaller than the first number of dies.

12. A method of manufacturing a semiconductor device, comprising:
forming at least one conductive structure on a substrate, the substrate including a die forming region and an edge die region;
forming a mold layer pattern on the substrate, the mold layer pattern including at least one opening exposing the conductive structure;
forming a conductive layer on sidewalls and a bottom of the opening and on an upper surface of the mold layer pattern;
forming a preliminary blocking layer on the conductive layer to fill the opening, forming the preliminary blocking layer including coating a photosensitive composition on the conductive layer, the photosensitive composition including a siloxane polymer, a cross-linking agent, a photoacid generator and a thermal acid generator;
selectively exposing to light a first portion of the preliminary blocking layer to form a first preliminary blocking pattern on the conductive layer in the edge die region of the substrate, the first preliminary blocking pattern including a cross-linked portion;
removing a second portion of the preliminary blocking layer, the second portion of the preliminary blocking layer being formed in the die forming region of the substrate, such that a second preliminary blocking pattern is formed in the opening of the mold layer pattern in the die forming region of the substrate;
curing the first and the second preliminary blocking patterns by a thermal treatment process to form a first blocking pattern in the edge die region and a second blocking pattern in the die forming region; and
removing a portion of the conductive layer in the die forming region to form at least one lower electrode in the die forming region.

13. The method as claimed in claim 12, further comprising:
removing the first blocking pattern from the edge die region, and the mold layer pattern and the second blocking pattern from the die forming region, after forming the lower electrode in the die forming region.

14. The method as claimed in claim 13, wherein removing the first and second blocking patterns and the mold layer pattern is performed using a solution including hydrogen fluoride, ammonium fluoride and water.

15. The method as claimed in claim 12, wherein forming the mold layer pattern on the substrate includes:
forming a mold layer on the substrate;
forming a photoresist film on the mold layer;
forming a photoresist pattern on the mold layer by performing an exposure process on the photoresist film using a first reticle defining a first reticle image corresponding to a first number of dies; and
etching the mold layer using the photoresist pattern as an etching mask to form the mold layer pattern on the substrate.

16. The method as claimed in claim 15, wherein selectively exposing to light the first portion of the preliminary blocking layer is performed using a second reticle defining a second reticle image corresponding to a second number of dies, the second number of dies being larger than zero and smaller than the first number of dies.

17. The method as claimed in claim 12, wherein the thermal treatment process is performed at a temperature of about 100° C. to about 300° C.
